(19) United States
(12) Patent Application Publication
(10) Pub. No.: US 2024/0206272 A1
(43) Pub. Date: Jun. 20, 2024

(54) ARRAY SUBSTRATE AND DISPLAY DEVICE

(71) Applicant: BOE TECHNOLOGY GROUP CO., LTD., Beijing (CN)

(72) Inventors: Shanshan BAI, Beijing (CN); Kuo SHEN, Beijing (CN); Lujiang HUANGFU, Beijing (CN); Hongli WANG, Beijing (CN)

(73) Assignee: BOE TECHNOLOGY GROUP CO., LTD., Beijing (CN)

(21) Appl. No.: 17/790,577

(22) PCT Filed: Mar. 16, 2021
(86) PCT No.: PCT/CN2021/081026

§ 371 Date: Jul. 1, 2022

(51) Int. Cl. H10K 59/35; H10K 59/122; H10K 59/131

(52) U.S. Cl. CPC H10K 59/353; H10K 59/122; H10K 59/131; H10K 59/351; H10K 59/352

(57) ABSTRACT

An array substrate and a display device are provided. The array substrate includes a plurality of sub-pixel groups, each sub-pixel group includes two first color sub-pixels, one second color sub-pixel and one third color sub-pixel; in each sub-pixel group, a first connection line between centers of the two first color sub-pixels intersects with a second connection line between a center of the second color sub-pixel and a center of the third color sub-pixel, and a length of an orthographic projection of a third connection line, between a center of one of the first color sub-pixels and the center of the second color sub-pixel, on the second connection line is different from a length of an orthographic projection of a fourth connection line, between the center of the one of the first color sub-pixels and the center of the third color sub-pixel, on the second connection line.

### TECHNICAL FIELD

Embodiments of the present disclosure relate to an array substrate and a display device.

### BACKGROUND

With the continuous development of display technology, people have higher and higher requirements for the resolution of display devices. Due to the advantages of high display quality or the like, the application range of high-resolution display devices is becoming wider and wider. Generally, the resolution of the display device can be improved by reducing the size of the pixel and reducing the spacing between pixels. However, the reduction of the size of the pixel and reduction of the spacing between pixels also require higher and higher precision of the manufacturing process, which will lead to an increase in the difficulty of the manufacturing process and manufacturing cost of the display device.

In another aspect, the sub-pixel rendering (SPR) technology can make use of the difference in the resolution of different color sub-pixels by the human eye to change the conventional mode of which one pixel is simply defined by red, green and blue sub-pixels. By sharing sub-pixels of resolution-insensitive colors at certain positions among different pixels, the same pixel resolution performance can be simulated and achieved with a relatively small number of sub-pixels, thereby reducing the difficulty of the manufacturing process and the manufacturing cost.

### SUMMARY

Embodiments of the present disclosure provide an array substrate and a display device. In the array substrate the distance between the first color sub-pixel and the second color sub-pixel is different from the distance between the same first color sub-pixel and the third color sub-pixel; that is, the distance between the first color sub-pixel and one of the second color sub-pixel and the third color sub-pixel to which the human eyes is more sensitive may be closer. Therefore, when the array substrate is used to display the vertical line, the “sense of fluctuation” of the vertical line seen by the human eyes can be alleviated because the first color sub-pixel may be closer to a sub-pixel which is more sensitive to human eyes among the second color sub-pixel and the third color sub-pixel, so that the graininess of the display image can be alleviated or even eliminated, and the lines of the display image can be more continuous and natural.

At least one embodiment of the present disclosure provides an array substrate, which includes: a plurality of sub-pixel groups, wherein each of the sub-pixel groups includes two first color sub-pixels, one second color sub-pixel, and one third color sub-pixel, in each of the sub-pixel groups, a first connection line between centers of the two first color sub-pixels intersects with a second connection line between a center of the second color sub-pixel and a center of the third color sub-pixel, and a length of an orthographic projection of a third connection line, between a center of one of the first color sub-pixels and the center of the second color sub-pixel, on the second connection line is different from a length of an orthographic projection of a fourth connection line, between the center of the one of the first color sub-pixels and the center of the third color sub-pixel, on the second connection line.

For example, in the array substrate provided by an embodiment of the present disclosure, the length of the orthographic projection of the third connection line, between the center of the one of the first color sub-pixels and the center of the second color sub-pixel, on the second connection line is greater than the length of the orthographic projection of the fourth connection line, between the center of the one of the first color sub-pixels and the center of the third color sub-pixel, on the second connection line.

For example, in the array substrate provided by an embodiment of the present disclosure, in each of the sub-pixel groups, in a direction of the third connection line, no other sub-pixel is provided between the first color sub-pixel and the second color sub-pixel; and in a direction of the fourth connection line, no other sub-pixel is provided between the first color sub-pixel and the third color sub-pixel.

For example, the array substrate provided by an embodiment of the present disclosure further includes: a sub-pixel interval, wherein the sub-pixel interval is provided between two adjacent sub-pixels, and the sub-pixel is any one selected from a group consisting of the first color sub-pixel, the second color sub-pixel, and the third color sub-pixel.

For example, in the array substrate provided by an embodiment of the present disclosure, the second connection line, the third connection line, and the fourth connection line form a non-equilateral triangle.

For example, in the array substrate provided by an embodiment of the present disclosure, a length of the third connection line is not equal to a length of the fourth connection line.

For example, in the array substrate provided by an embodiment of the present disclosure, the two first color sub-pixels are mirror-symmetrical with respect to the second connection line.

For example, in the array substrate provided by an embodiment of the present disclosure, the plurality of sub-pixel groups are arranged along a first direction to form a plurality of sub-pixel group rows, the plurality of sub-pixel groups are arranged along a second direction intersecting with the first direction to form a plurality of sub-pixel group columns, and two adjacent sub-pixel group columns are in a staggered arrangement; and in the sub-pixel group column, two adjacent sub-pixel groups include a first sub-pixel group and a second sub-pixel group, and a minimum distance between a center of the first color sub-pixel in the first sub-pixel group and a center of the first color sub-pixel in the second sub-pixel group is smaller than a length of the first connection line.

For example, in the array substrate provided by an embodiment of the present disclosure, the length of the first connection line is less than 90 μm.

For example, in the array substrate provided by an embodiment of the present disclosure, two adjacent first color sub-pixels in a first direction overlap with a straight line extending in the first direction.

For example, in the array substrate provided by an embodiment of the present disclosure, centers of two first color sub-pixels in the first sub-pixel group and centers of two first color sub-pixels in the second sub-pixel group are on one straight line.

For example, in the array substrate provided by an embodiment of the present disclosure, the plurality of sub-pixel groups are arranged along a first direction to form a plurality of sub-pixel group rows, the plurality of sub-pixel groups are arranged along a second direction intersecting with the first direction to form a plurality of sub-pixel group columns, and two adjacent sub-pixel group columns are in a staggered arrangement; and in the sub-pixel group column, two adjacent sub-pixel groups include a first sub-pixel group and a second sub-pixel group, and a ratio of a maximum distance of vertices of two first color sub-pixels with a minimum spacing in the first sub-pixel group and the second sub-pixel group, to a size of the second color sub-pixel in an extending direction of the first connection line ranges from 0.8 to 1.2.

For example, in the array substrate provided by an embodiment of the present disclosure, a shape of the first color sub-pixel is a non-centrally symmetric polygon, a shape of the second color sub-pixel is a non-centrally symmetric polygon, and a shape of the third color sub-pixel is a non-centrally symmetric polygon.

For example, in the array substrate provided by an embodiment of the present disclosure, a ratio of a size of a shape of the first color sub-pixel in an extending direction of the first connection line to a size of a shape of the first color sub-pixel in an extending direction of the second connection line ranges from 1.6 to 2.8; and/or a ratio of a size of a shape of the second color sub-pixel in the extending direction of the first connection line to a size of a shape of the second color sub-pixel in the extending direction of the second connection line ranges from 4.3 to 6.7; and/or a ratio of a size of a shape of the third color sub-pixel in the extending direction of the first connection line to a size of a shape of the third color sub-pixel in the extending direction of the second connection line ranges from 0.4 to 0.76.

For example, in the array substrate provided by an embodiment of the present disclosure, in each of the sub-pixel groups, an orthographic projection of the second color sub-pixel on the first connection line overlaps with an orthographic projection of the first color sub-pixel on the first connection line, and an orthographic projection of the third color sub-pixel on the first connection line is not overlapped with the orthographic projection of the first color sub-pixel on the first connection line.

For example, in the array substrate provided by an embodiment of the present disclosure, in each of the sub-pixel groups, an orthographic projection of the first color sub-pixel on the second connection line overlaps with an orthographic projection of the third color sub-pixel on the second connection line.

For example, in the array substrate provided by an embodiment of the present disclosure, at least one of a group consisting of a shape of the first color sub-pixel, a shape of the second color sub-pixel, and a shape of the third color sub-pixel includes a pair of parallel edges, and the pair of parallel edges includes two parallel edges.

For example, in the array substrate provided by an embodiment of the present disclosure, at least one of a group consisting of a shape of the second color sub-pixel and a shape of the third color sub-pixel includes a pair of parallel edges, the pair of parallel edges includes a first parallel edge and a second parallel edge, and a length of the first parallel edge is greater than a length of the second parallel edge; and a distance between the first parallel edge and the first connection line is greater than a distance between the second parallel edge and the first connection line.

For example, in the array substrate provided by an embodiment of the present disclosure, at least one of the group consisting of the shape of the second color sub-pixel and the shape of the third color sub-pixel is symmetrical with respect to the second connection line.

For example, in the array substrate provided by an embodiment of the present disclosure, at least one of a group consisting of a shape of the second color sub-pixel and a shape of the third color sub-pixel includes a polygon, the polygon includes two vertices, and a distance between the two vertices is a maximum size of the polygon in a second direction; and the polygon is divided, by a connection line between the two vertices, into a first portion and a second portion which are on both sides of the connection line, and an area of the first portion is not equal to an area of the second portion.

For example, in the array substrate provided by an embodiment of the present disclosure, the polygon includes a first edge and a second edge, the first edge and the second edge are parallel to each other and parallel to the connection line between the two vertices, a length of the first edge is greater than a length of the second edge, the first portion is a portion where the first edge of the polygon is located, the second portion is a portion where the second edge of the polygon is located, and a size of the first portion in the first direction is smaller than a size of the second portion in the first direction.

For example, in the array substrate provided by an embodiment of the present disclosure, an area of the second color sub-pixel is greater than an area of the third color sub-pixel.

For example, in the array substrate provided by an embodiment of the present disclosure, a shape of the first color sub-pixel includes a pair of parallel edges, the pair of parallel edges includes two parallel edges, and in one of the sub-pixel groups, a length of one of the two parallel edges close to the second color sub-pixel is smaller than a length of another of the two parallel edges close to the third color sub-pixel.

For example, in the array substrate provided by an embodiment of the present disclosure, a shape of the first color sub-pixel is symmetrical with respect to an extending direction of the first connection line.

For example, the array substrate provided by an embodiment of the present disclosure further includes: a base substrate; a first color pixel electrode, a second color pixel electrode, and a third color pixel electrode, which are on the base substrate; a pixel defining layer, wherein the pixel defining layer is on a side of the first color pixel electrode, the second color pixel electrode, and the third color pixel electrode away from the base substrate, the pixel defining layer includes a first opening, a second opening, and a third opening, the first opening exposes the first color pixel electrode, the second opening exposes the second color pixel electrode, and the third opening exposes the third color pixel electrode; a first color light-emitting layer, wherein the first color light-emitting layer is on a side of the pixel defining layer away from the first color pixel electrode, and the first color light-emitting layer covers, through the first opening, a portion of the first color pixel electrode exposed by the first opening; a second color light-emitting layer, wherein the second color light-emitting layer is on a side of the pixel defining layer away from the second color pixel electrode, and the second color light-emitting layer covers, through the second opening, a portion of the second color pixel electrode exposed by the second opening; and a third color light-emitting layer, wherein the third color light-emitting layer is on a side of the pixel defining layer away from the third color pixel electrode, and the third color light-emitting layer covers, through the third opening, a portion of the third color pixel electrode exposed by the third opening, a shape and a size of the first color sub-pixel are defined by the first opening, a shape and a size of the second color sub-pixel are defined by the second opening, and a shape and a size of the third color sub-pixel are defined by the third opening.

For example, in the array substrate provided by an embodiment of the present disclosure, two first color light-emitting layers of two adjacent first color sub-pixels in an extending direction of the first connection line are integrated into one first color integrated light-emitting layer, and an orthographic projection of the first color integrated light-emitting layer on the base substrate covers two first openings.

At least one embodiment of the present disclosure further provides a display device, which includes the array substrate.

### BRIEF DESCRIPTION OF THE DRAWINGS

In order to clearly illustrate the technical solution of the embodiments of the present disclosure, the drawings of the embodiments will be briefly described. It is apparent that the described drawings are only related to some embodiments of the present disclosure and thus are not limitative of the present disclosure.

FIG. 1 is a schematic diagram of an array substrate;

FIG. 2A is a schematic planar diagram of an array substrate provided by an embodiment of the present disclosure;

FIG. 2B is a schematic planar diagram of another array substrate provided by an embodiment of the present disclosure;

FIG. 3 is a schematic diagram of another array substrate provided by an embodiment of the present disclosure;

FIG. 4A is a schematic diagram of another array substrate provided by an embodiment of the present disclosure;

FIG. 4B is a schematic diagram of another array substrate provided by an embodiment of the present disclosure;

FIG. 5 is a schematic diagram of another array substrate provided by an embodiment of the present disclosure;

FIG. 6 is a schematic diagram of another array substrate provided by an embodiment of the present disclosure;

FIG. 7 is a schematic diagram of another array substrate provided by an embodiment of the present disclosure;

FIG. 8 is a schematic diagram of another array substrate provided by an embodiment of the present disclosure;

FIG. 9 is a schematic diagram of another array substrate provided by an embodiment of the present disclosure;

FIG. 10 is a schematic cross-sectional view of an array substrate along a direction AA′ in FIG. 9 provided by an embodiment of the present disclosure;

FIG. 11 is a schematic diagram of another array substrate provided by an embodiment of the present disclosure; and

FIG. 12 is a schematic diagram of a display device provided by an embodiment of the present disclosure.

### DETAILED DESCRIPTION

In order to make objects, technical details and advantages of embodiments of the present disclosure clear, the technical solutions of the embodiments will be described in a clearly and fully understandable way in connection with the related drawings. It is apparent that the described embodiments are just a part but not all of the embodiments of the present disclosure. Based on the described embodiments herein, those skilled in the art can obtain, without any inventive work, other embodiment(s) which should be within the scope of the present disclosure.

Unless otherwise defined, all the technical and scientific terms used herein have the same meanings as commonly understood by one of ordinary skill in the art to which the present disclosure belongs. The terms “first,” “second,” etc., which are used in the description and claims of the present disclosure, are not intended to indicate any sequence, amount or importance, but distinguish various components. The terms “comprises,” “comprising,” “includes,” “including,” etc., are intended to specify that the elements or the objects stated before these terms encompass the elements or the objects listed after these terms as well as equivalents thereof, but do not exclude other elements or objects. The phrases “connect”, “connected”, etc., are not intended to define a physical connection or a mechanical connection, but may comprise an electrical connection which is direct or indirect.

Although, the sub-pixel rendering (SPR) technology can use a relatively small number of sub-pixels to simulate the performance of the equivalent pixel resolution, so as to reduce the difficulty of the manufacturing process and the manufacturing cost, the pixel arrangement structure using the sub-pixel rendering (SPR) technology will cause some display flaws, such as grainy display images, discontinuous lines in the display images, or the like.

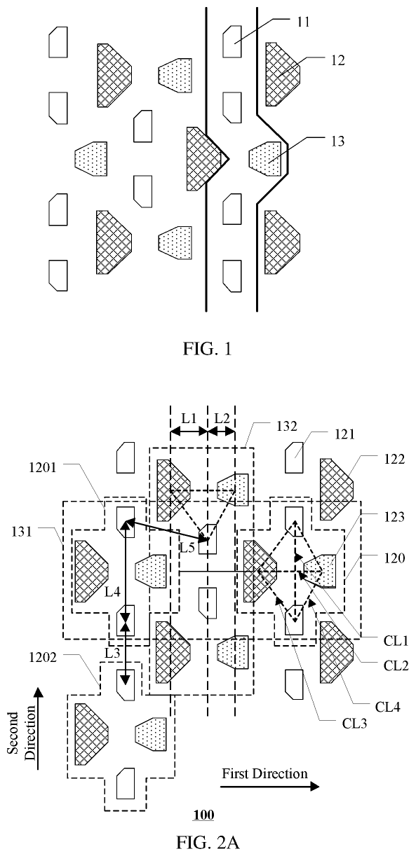

FIG. 1 is a schematic diagram of an array substrate. As illustrated in FIG. 1, the array substrate 10 includes a first color sub-pixel 11, a second color sub-pixel 12, and a third color sub-pixel 13. The color of the light emitted by the first color sub-pixel 11 and the color of the light emitted by the third color sub-pixel 13 may be a color sensitive to human eyes, that is, when the human eyes perform visual synthesis, the color of the light emitted by the first color sub-pixel 11 and the color of the light emitted by the third color sub-pixel 13 have a higher proportion. As illustrated in FIG. 1, when the array substrate is used for vertical lines, because the distance between the first color sub-pixel and the third color sub-pixel is relatively far, the vertical line seen by the human eyes has a strong “sense of fluctuation,” which may cause the graininess of the display image and make the lines of the display image discontinuous.

In this regard, the embodiments of the present disclosure provide an array substrate and a display device. The array substrate includes a plurality of sub-pixel groups, and each sub-pixel group includes two first color sub-pixels, one second color sub-pixel, and one third color sub-pixel; and in each of the sub-pixel groups, a first connection line between centers of the two first color sub-pixels intersects with a second connection line between a center of the second color sub-pixel and a center of the third color sub-pixel, and a length of an orthographic projection of a third connection line, between a center of one of the first color sub-pixels and the center of the second color sub-pixel, on the second connection line is different from a length of an orthographic projection of a fourth connection line, between the center of the one of the first color sub-pixels and the center of the third color sub-pixel, on the second connection line. Therefore, in the extending direction of the second connection line, the distance between the first color sub-pixel and the second color sub-pixel is different from the distance between the same first color sub-pixel and the third color sub-pixel; that is, in the extending direction of the second connection line, the distance between the first color sub-pixel and the second color sub-pixel or the third color sub-pixel may be closer. Therefore, when the array substrate is used to display the vertical line extending in the extending direction of the first connection line, and each first color sub-pixel provides a color sensitive to human eyes, the “sense of fluctuation” of the vertical line seen by the human eyes can be alleviated because the first color sub-pixel may be closer to a sub-pixel more sensitive to human eyes among the second color sub-pixel and the third color sub-pixel, so that the graininess of the display image can be alleviated or even eliminated, and the lines of the display image can be more continuous and natural.

Hereinafter, the array substrate and the display device provided by the embodiments of the present disclosure will be described with reference to the accompanying drawings.

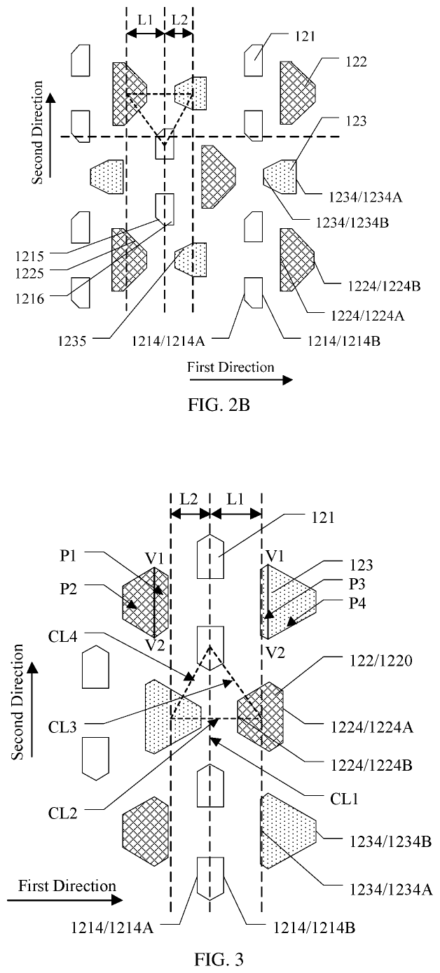

An embodiment of the present disclosure provides an array substrate. FIG. 2A is a schematic planar diagram of an array substrate provided by an embodiment of the present disclosure, and FIG. 2B is a schematic planar diagram of another array substrate provided by an embodiment of the present disclosure. As illustrated in FIG. 2A, the array substrate 100 includes a plurality of sub-pixel groups 120, and each sub-pixel group 120 includes two first color sub-pixels 121, one second color sub-pixel 122, and one third color sub-pixel 123. For example, the first color sub-pixel 121 is configured to emit light of a first color, the second color sub-pixel 122 is configured to emit light of a second color, and the third color sub-pixel 123 is configured to emit light of a third color.

For example, the first color may be green, the second color may be blue, and the third color may be red. Certainly, the embodiments of the present disclosure include but are not limited thereto.

As illustrated in FIG. 2A, in each sub-pixel group 120, the first connection line CL1 between the centers of the two first color sub-pixels 121 intersects with the second connection line CL2 between the center of the second color sub-pixel 122 and the center of the third color sub-pixel 123, and the length L1 of the orthographic projection of the third connection line CL3 between the center of one first color sub-pixel 121 and the center of the second color sub-pixel 122 on the second connection line CL2 is different from the length L2 of the orthographic projection of the fourth connection line CL4 between the center of the same one first color sub-pixel 121 and the center of the third color sub-pixel 123 on the second connection line CL2. It should be noted that the above-mentioned “center” refers to a luminance center or a geometric center of the effective light-emitting region of the sub-pixel.

In the array substrate provided by the embodiments of the present disclosure, as illustrated in FIG. 2B, the length L1 of the orthographic projection of the third connection line CL3 between the center of one first color sub-pixel 121 and the center of the second color sub-pixel 122 on the second connection line CL2 is greater than the length L2 of the orthographic projection of the fourth connection line CL4 between the center of the same one first color sub-pixel 121 and the center of the third color sub-pixel 123 on the second connection line CL2. That is, in the extending direction of the second connection line CL2, the distance between the first color sub-pixel 121 and the second color sub-pixel 122 is greater than the distance between the first color sub-pixel 121 and the third color sub-pixel 123; and in the extending direction of the second connection line CL2, the distance between the first color sub-pixel 121 and the third color sub-pixel 123 is closer. Therefore, when the array substrate is used to display the vertical lines extending in the extending direction of the first connection line CL1, and both of the first color sub-pixel 121 and the third color sub-pixel 123 provide sensitive colors for human eyes, because the distance between the first color sub-pixel 121 and the third color sub-pixel 123 is closer, the “sense of fluctuation” of the vertical lines seen by human eyes can be alleviated, so that the graininess of the display image can be alleviated or even eliminated, and the lines of the display image can be more continuous and natural.

In the array substrate provided by the embodiments of the present disclosure, as illustrated in FIG. 2B, the two first color sub-pixels 121 in one sub-pixel group 120 may share the second color sub-pixel 122 and the third color sub-pixel 123, thereby forming two pixel points, so that a relatively small number of sub-pixels can be used to achieve higher pixel resolution.

In some examples, the length of the orthographic projection of the third connection line between the center of one first color sub-pixel and the center of the second color sub-pixel on the second connection line is greater than the length of the orthographic projection of the fourth connection line between the center of the same one first color sub-pixel and the center of the third color sub-pixel on the second connection line, and the light-emitting efficiency of the second color sub-pixel is lower than the light-emitting efficiency of the third color sub-pixel. In the field of organic light-emitting display, the light-emitting efficiency of the light-emitting element that emits blue light is generally lower than the light-emitting efficiency of the light-emitting element that emits red light, and human eyes are more sensitive to red light than to blue light. For example, the light-emitting efficiency of the first color sub-pixel may be greater than the light-emitting efficiency of the third color sub-pixel.

In some examples, the light-emitting area of a single second color sub-pixel is larger than the light-emitting area of a single third color sub-pixel. Due to factors such as the service life and light-emitting efficiency, the light-emitting area of the sub-pixel emitting blue light is generally larger than the light-emitting area of the sub-pixel emitting red light.

In some examples, the light-emitting area of a single third color sub-pixel may be larger than the light-emitting area of a single first color sub-pixel.

In some examples, the luminous intensity per unit area of the second color sub-pixel is less than the luminous intensity per unit area of the third color sub-pixel, and the luminous intensity per unit area of the third color sub-pixel is less than the luminous intensity per unit area of the first color sub-pixel.

In some examples, the wavelength of the light emitted by the second color sub-pixel is smaller than the wavelength of the light emitted by the third color sub-pixel. In addition, the wavelength of the light emitted by the first color sub-pixel is between the wavelength of the light emitted by the second color sub-pixel and the wavelength of the light emitted by the third color sub-pixel.

In some examples, a ratio of the length L1 of the orthographic projection of the third connection line CL3 between the center of the first color sub-pixel 121 and the center of the second color sub-pixel 122 on the second connection line CL2 to the length L2 of the orthographic projection of the fourth connection line CL4 between the center of the first color sub-pixel 121 and the center of the third color sub-pixel 123 on the second connection line CL2 may range from 1 to 3. For example, as illustrated in FIG. 2B, a ratio of the length L1 of the orthographic projection of the third connection line CL3 between the center of the first color sub-pixel 121 and the center of the second color sub-pixel 122 on the second connection line CL2 to the length L2 of the orthographic projection of the fourth connection line CL4 between the center of the first color sub-pixel 121 and the center of the third color sub-pixel 123 on the second connection line CL2 may range from 1 to 1.5.

In some examples, as illustrated in FIG. 2A, the second connection line CL2, the third connection line CL3, and the fourth connection line CL4 form a non-equilateral triangle.

In some examples, as illustrated in FIG. 2A, the length of the third connection line CL3 is not equal to the length of the fourth connection line CL4.

In some examples, as illustrated in FIG. 2A, the two first color sub-pixels 121 are mirror-symmetrical with respect to the second connection line CL2. Thus, the array substrate can increase the symmetry of two pixel points in the sub-pixel group.

For example, as illustrated in FIG. 2A, the second color sub-pixel 122 and the third color sub-pixel 123 are also mirror-symmetrical with respect to the second connection line CL2, that is, the second color sub-pixel 122 and the third color sub-pixel 123 are mirror-symmetrical with respect to the straight line extending along the extending direction of the second connection line CL2.

In some examples, as illustrated in FIG. 2A, a plurality of sub-pixel groups 120 are arranged along a first direction to form a plurality of sub-pixel group rows 131, and are arranged along a second direction intersecting with the first direction to form a plurality of sub-pixel group columns 132, and two adjacent sub-pixel group columns 132 are in a staggered arrangement. It should be noted that, the above-mentioned “staggered arrangement” means that two adjacent sub-pixel group columns 132 are not aligned, but are staggered by a certain distance in the second direction. For example, two adjacent sub-pixel group columns 132 may be staggered at a ½ pitch, and the above-mentioned pitch is the distance between the centers of the second color sub-pixels in the two adjacent sub-pixel groups in the second direction.

In some examples, as illustrated in FIG. 2A, in the sub-pixel group column 132, two adjacent sub-pixel groups 120 include a first sub-pixel group 1201 and a second sub-pixel group 1202. The minimum distance L3 between the center of the first color sub-pixel 121 in the first sub-pixel group 1201 and the center of the first color sub-pixel 121 in the second sub-pixel group 1202 is less than the length L4 of the first connection line CL1, and the length L4 of the first connection line CL1 is less than 90 μm, for example, less than 78 μm or less than 56 μm. because the retinal recognition limit of human eyes is 78 μm, when the length of the first connection line CL1 is less than 78 μm, that is, when the distance between the centers of the two first color sub-pixels 121 is less than 78 μm, human eyes will not easily recognize the uneven graininess caused by the difference in the spacing between the two first color sub-pixels 121, thereby being beneficial to the screen display effect.

In some examples, as illustrated in FIG. 2A, the minimum distance L4 between the center of the first color sub-pixel 121 in the first sub-pixel group 1201 and the center of the first color sub-pixel 121 in the second sub-pixel group 1202 is less than or equal to the minimum distance L5 between the centers of two adjacent first color sub-pixels 121 in the first direction. It should be noted that the above-mentioned two adjacent first color sub-pixels in the first direction may be a lower first color sub-pixel in a sub-pixel group in a sub-pixel group row and an upper first color sub-pixel in a sub-pixel group adjacent to the above-mentioned sub-pixel group in an adjacent sub-pixel group row.

In some examples, as illustrated in FIG. 2A and FIG. 2B, two adjacent first color sub-pixels in the first direction overlap with a straight line extending in the first direction. That is, a straight line extending in the first direction may simultaneously pass through two adjacent first color sub-pixels in the first direction.

In some examples, the centers of two adjacent first color sub-pixels in the first direction may be located on a straight line extending in the first direction, that is, a straight line extending in the first direction may simultaneously pass through the centers of two adjacent first color sub-pixels in the first direction. For example, as illustrated in FIG. 2A, a sum of the minimum distance L3 between the center of the first color sub-pixel 121 in the first sub-pixel group 1201 and the center of the first color sub-pixel 121 in the second sub-pixel group 1202 and the length L4 of the first connection line CL1 may be twice the pitch.

For example, the above-mentioned first direction and second direction are perpendicular to each other, and the first direction and the second direction being perpendicular to each other includes the situation that the first direction and the second direction are strictly perpendicular, and also includes the situation that the angle between the first direction and the second direction ranges from 80 degrees to 100 degrees.

For example, as illustrated in FIG. 2A, the first direction may be the extending direction of the second connection line CL2, and the second direction may be the extending direction of the first connection line CL1. Of course, the embodiments of the present disclosure include but are not limited thereto.

In some examples, as illustrated in FIG. 2A, the centers of the two first color sub-pixels 121 in the first sub-pixel group 1201 and the centers of the two first color sub-pixels 121 in the second sub-pixel group 1202 are located on the same straight line.

For example, as illustrated in FIG. 2A, the centers of all the first color sub-pixels 121 in one sub-pixel group column 132 may be located on the same straight line.

In some examples, as illustrated in FIG. 2B, the shape of the first color sub-pixel 121 is a non-centrally symmetrical polygon, the shape of the second color sub-pixel 122 is a non-centrally symmetrical polygon, and the shape of the third color sub-pixel 123 is a non-centrally symmetrical polygon. Thus, the area of the array substrate can be fully utilized, thereby increasing the aperture ratio.

For example, the number of sides of each of the above-mentioned shape of the first color sub-pixel 121, the above-mentioned shape of the second color sub-pixel 122, and the above-mentioned shape of the third color sub-pixel 123 is greater than five.

In some examples, at least one of a group consisting of the shape of the first color sub-pixel 121, the shape of the second color sub-pixel 122, and the shape of the third color sub-pixel 123 includes a pair of parallel edges, and the pair of parallel edges includes two parallel edges.

As illustrated in FIG. 2B, the shape of the first color sub-pixel 121 includes a pair of parallel edges 1214, and the pair of parallel edges 1214 includes two parallel edges 1214A and 1214B; the shape of the second color sub-pixel 122 includes a pair of parallel edges 1224, and the pair of parallel edges 1224 includes two parallel edges 1224A and 1224B; and the shape of the third color sub-pixel 123 includes a pair of parallel edges 1234, and the pair of parallel edges 1234 includes two parallel edges 1234A and 1234B.

Therefore, when a fine metal mask (FMM) is used to fabricate the above-mentioned array substrate, the extending direction of the above-mentioned parallel edges can be the stretching direction of the fine metal mask (FMM), which is beneficial to the transmission of the fine metal mask (FMM) tension, thereby improving the product yield. It should be noted that the shape of the first color sub-pixel, the shape of the second color sub-pixel, and the shape of the third color sub-pixel in the array substrate shown in FIG. 2A and FIG. 2B all include a pair of parallel edges, but the embodiments of the present disclosure include but are not limited thereto, and the shape of at least one of the first color sub-pixel, the second color sub-pixel, and the third color sub-pixel includes a pair of parallel edges, which may also be beneficial to the transmission of the fine metal mask (FMM) tension, thereby improving the product yield.

For example, as illustrated in FIG. 2A, the parallel edges included in at least one of a group consisting of the shape of the first color sub-pixel 121, the shape of the second color sub-pixel 122, and the shape of the third color sub-pixel 123 may be parallel to the second direction. In this case, the second direction may be the stretching direction of the fine metal mask (FMM).

In some examples, at least one of a group consisting of the shape of the second color sub-pixel 122 and the shape of the third color sub-pixel 123 includes a pair of parallel edges, the pair of parallel edges includes a first parallel edge and a second parallel edge, the length of the first parallel edge is greater than that of the second parallel edge, and the distance between the first parallel edge and the first connection line is greater than the distance between the second parallel edge and the first connection line.

In some examples, as illustrated in FIG. 2A, in one sub-pixel group, the length of one of the two parallel edges close to the second color sub-pixel 122 is smaller than the length of one of the two parallel edges close to the third color sub-pixel 123.

As illustrated in FIG. 2B, the shape of the second color sub-pixel 122 includes a pair of parallel edges 1224, the pair of parallel edges 1224 includes a first parallel edge 1224A and a second parallel edge 1224B, the length of the first parallel edge 1224A is greater than that of the second parallel edge 1224B, and the distance between the first parallel edge 1224A and the first connection line CL1 is greater than the distance between the second parallel edge 1224B and the first connection line CL1. The shape of the third color sub-pixel 123 includes a pair of parallel edges 1234, the pair of parallel edges 1234 includes a first parallel edge 1234A and a second parallel edge 1234B, the length of the first parallel edge 1234A is greater than that of the second parallel edge 1234B, and the distance between the first parallel edge 1234A and the first connection line CL1 is greater than the distance between the second parallel edge 1234B and the first connection line CL1. Because the space between the second color sub-pixel 122 and the third color sub-pixel 123 is provided with two first color sub-pixels 121, the above-mentioned arrangement can make full use of the space and improve the aperture ratio.

In some examples, as illustrated in FIG. 2B, at least one of the shape of the second color sub-pixel 122 and the shape of the third color sub-pixel 123 is symmetrical with respect to the second connection line CL2.

In some examples, as illustrated in FIG. 2B, the area of the second color sub-pixel 122 is larger than the area of the third color sub-pixel 123. Due to the difference in the structure design and material system of the light-emitting device, the sub-pixels (e.g., the first color sub-pixel 121, the second color sub-pixel 122, and the third color sub-pixel 123 described above) emitting different colors have difference in service life. Therefore, by setting the area of the second color sub-pixel 122 to be larger than that of the third color sub-pixel 123, the above-mentioned difference in service life can be balanced, and the overall service life of the array substrate can be improved.

In some examples, as illustrated in FIG. 2B, the shape of the first color sub-pixel 121 includes a first bevel edge 1215 and a first right angle 1216, the shape of the second color sub-pixel 122 includes a second bevel edge 1225, the first bevel edge 1215 is parallel to the second bevel edge 1225, the shape of the third color sub-pixel 123 includes a third bevel edge 1235, and the third bevel edge 1235 is opposite to the first right angle 1216. Therefore, because the area of the second color sub-pixel 122 is larger than that of the third color sub-pixel 123, the first bevel edge 1215 of the first color sub-pixel 121 can be opposite to the second bevel edge 1225 of the second color sub-pixel 122, so as to increase the area of the first color sub-pixel and the second color sub-pixel as much as possible under the limitation of process accuracy, and the first right angle 1216 of the first color sub-pixel 121 is opposite to the third bevel edge 1235 of the third color sub-pixel 123, so as to make full use of the interval between the first color sub-pixel 121 and the third color sub-pixel 123, thereby making full use of the area of the array substrate and improving the aperture ratio.

FIG. 3 is a schematic diagram of another array substrate provided by an embodiment of the present disclosure. As illustrated in FIG. 3, in each sub-pixel group 120, the first connection line CL1 between the centers of the two first color sub-pixels 121 intersects with the second connection line CL2 between the center of the second color sub-pixel 122 and the center of the third color sub-pixel 123, and the length L1 of the orthographic projection of the third connection line CL3 between the center of any first color sub-pixel 121 and the center of the second color sub-pixel 122 on the second connection line CL2 is greater than the length L2 of the orthographic projection of the fourth connection line CL4 between the center of the first color sub-pixel 121 and the center of the third color sub-pixel 123 on the second connection line CL2. Similarly, in the extending direction of the second connection line CL2, the distance between the first color sub-pixel 121 and the second color sub-pixel 122 is greater than the distance between the first color sub-pixel 121 and the third color sub-pixel 123; that is, in the extending direction of the second connection line CL2, the distance between the first color sub-pixel 121 and the third color sub-pixel 123 is closer. Therefore, when the array substrate is used to display the vertical lines extending along the extending direction of the first connection line CL1, and the first color sub-pixel 121 and the third color sub-pixel 123 both provide sensitive colors for human eyes, because the first color sub-pixel 121 is closer to the third color sub-pixel 123, the “sense of fluctuation” of the vertical lines seen by human eyes can be alleviated, so that the graininess of the display image can be alleviated or even eliminated, and the lines of the display image can be more continuous and natural.

In some examples, as illustrated in FIG. 3, the shape of the second color sub-pixel 122 is a polygon 1220, the polygon 1220 includes two vertices V1 and V2, the distance between the two vertices V1 and V2 is a maximum size of the polygon 1220 in the second direction, the polygon 1220 is divided, by the connection line between the two vertices V1 and V2, into a first portion P1 and a second portion P2 which are on both sides of the connection line, and the area of the first portion P1 is not equal to the area of the second portion P2.

For example, as illustrated in FIG. 3, the polygon includes a first edge and a second edge, the first edge and the second edge are parallel to each other and parallel to the line connecting the two vertices, the length of the first edge is greater than that of the second edge, the first portion is a portion where the first edge of the polygon is located, the second portion is a portion where the second edge of the polygon is located, and a size of the first portion P1 in the first direction is smaller than a size of the second portion P2 in the first direction.

In some examples, as illustrated in FIG. 3, the shape of the third color sub-pixel 123 is a polygon 1230, the polygon 1230 includes two vertices V3 and V4, the distance between the two vertices V3 and V4 is a maximum size of the polygon 1230 in the second direction, the polygon 1230 is divided, by the connection line between the two vertices V3 and V4, into a first portion P3 and a second portion P4 which are on both sides of the connection line, and the area of the first portion P3 is not equal to the area of the second portion P4.

For example, as illustrated in FIG. 3, the size of the first portion P3 in the first direction is smaller than the size of the second portion P4 in the first direction.

In some examples, as illustrated in FIG. 3, the shape of the first color sub-pixel 121 is symmetrical with respect to the extending direction of the first connection line CL1.

For example, as illustrated in FIG. 3, the shape of the first color sub-pixel 121 includes a right-angled base symmetrical pentagon, the right-angled base symmetrical pentagon is symmetrical with respect to the first connection line CL, and the base of the right-angled base symmetrical pentagon is on a side of the vertex of the right-angled base symmetrical pentagon away from the second connection line CL2.

In some examples, as illustrated in FIG. 3, the order of the second color sub-pixel 122 and the third color sub-pixel 123 in the extending direction of the second connection line CL2 may be interchanged.

In some examples, as illustrated in FIG. 3, the shape of the first color sub-pixel 121 includes a pair of parallel edges 1214, and the pair of parallel edges 1214 includes two parallel edges 1214A and 1214B; the shape of the second color sub-pixel 122 includes a pair of parallel edges 1224, and the pair of parallel edges 1224 includes two parallel edges 1224A and 1224B; and the shape of the third color sub-pixel 123 includes a pair of parallel edges 1234, and the pair of parallel edges 1234 includes two parallel edges 1234A and 1234B. Thus, when a fine metal mask (FMM) is used to fabricate the above-mentioned array substrate, the extending direction of the above-mentioned parallel edges can be the stretching direction of the fine metal mask (FMM), which is beneficial to the transmission of the fine metal mask (FMM) tension, thereby improving the product yield.

In some examples, as illustrated in FIG. 3, the shape of the second color sub-pixel 122 includes a hexagon, the hexagon includes a parallel edge group and two opposite side groups, the parallel edge group includes two parallel edges which are parallel to each other, and each opposite side group includes two opposite sides which are disposed opposite to each other. Similarly, the shape of the third color sub-pixel 123 also includes a hexagon, the hexagon includes a parallel edge group and two opposite side groups, the parallel edge group includes two parallel edges which are parallel to each other, and each opposite side group includes two opposite sides which are disposed opposite to each other.

For example, as illustrated in FIG. 3, the first color sub-pixel 121 is configured to emit green light, the second color sub-pixel 122 is configured to emit blue light, and the third color sub-pixel 123 is configured to emit red light.

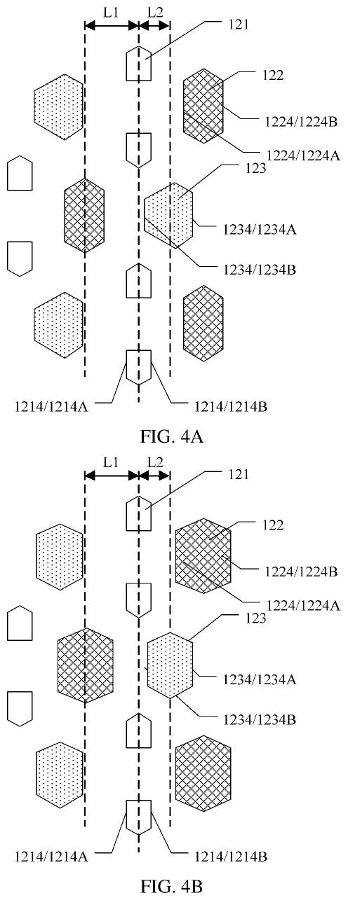

FIG. 4A is a schematic diagram of another array substrate provided by an embodiment of the present disclosure. As illustrated in FIG. 4A, in each sub-pixel group 120, the first connection line CL1 between the centers of the two first color sub-pixels 121 intersects with the second connection line CL2 between the center of the second color sub-pixel 122 and the center of the third color sub-pixel 123, and the length L1 of the orthographic projection of the third connection line CL3 between the center of any first color sub-pixel 121 and the center of the second color sub-pixel 122 on the second connection line CL2 is greater than the length L2 of the orthographic projection of the fourth connection line CL4 between the center of the first color sub-pixel 121 and the center of the third color sub-pixel 123 on the second connection line CL2. Similarly, in the extending direction of the second connection line CL2, the distance between the first color sub-pixel 121 and the second color sub-pixel 122 is greater than the distance between the first color sub-pixel 121 and the third color sub-pixel 123; that is, in the extending direction of the second connection line CL2, the distance between the first color sub-pixel 121 and the third color sub-pixel 123 is closer. Therefore, when the array substrate is used to display the vertical lines extending along the extending direction of the first connection line CL1, and the first color sub-pixel 121 and the third color sub-pixel 123 both provide sensitive colors for human eyes, because the first color sub-pixel 121 is closer to the third color sub-pixel 123, the “fluctuation” of the vertical lines seen by human eyes can be alleviated, so that the graininess of the display image can be alleviated or even eliminated, and the lines of the display image can be more continuous and natural.

As illustrated in FIG. 4A, the shape of the third color sub-pixel 123 includes a pair of parallel edges 1234, the pair of parallel edges 1234 includes a first parallel edge 1234A and a second parallel edge 1234B, the length of the first parallel edge 1234A is greater than that of the second parallel edge 1234B, and the distance between the first parallel edge 1234A and the first connection line CL1 is greater than the distance between the second parallel edge 1234B and the first connection line CL1. Because the space between the second color sub-pixel 122 and the third color sub-pixel 123 is provided with two first color sub-pixels 121, the above arrangement can make full use of the space and improve the aperture ratio.

For example, as illustrated in FIG. 4A, the shape of the third color sub-pixel 123 includes a pair of parallel edges 1234, the pair of parallel edges 1234 includes a first parallel edge 1234A and a second parallel edge 1234B, and the length of the first parallel edge 1234A is the same as the length of the second parallel edge 1234B.

FIG. 4B is a schematic diagram of another array substrate provided by an embodiment of the present disclosure. As illustrated in FIG. 4B, the shapes of the first color sub-pixel 121, the second color sub-pixel 122 and the third color sub-pixel 123 are all symmetrical shapes. Further, the shapes of the first color sub-pixel 121, the second color sub-pixel 122 and the third color sub-pixel 123 are all left-right symmetrical hexagons.

For example, as illustrated in FIG. 4B, the shape of the second color sub-pixel 122 and the third color sub-pixel 123 has a smaller ratio (aspect ratio) of the size in the second direction to the size in the first direction than that, a ratio (aspect ratio) of the size in the second direction to the size in the first direction, of the shape of the first color sub-pixel 121.

For example, the size of the shape of the second color sub-pixel 122 in the second direction is approximately the same as the size of the shape of the second color sub-pixel 122 in the first direction, and the size of the shape of the third color sub-pixel 123 in the second direction is approximately the same as the size of the shape of the third color sub-pixel 123 in the first direction; that is, the shape of the second color sub-pixel 122 and the shape of the third color sub-pixel 123 may be a regular hexagon.

FIG. 5 is a schematic diagram of another array substrate provided by an embodiment of the present disclosure. As illustrated in FIG. 5, in each sub-pixel group 120, the first connection line CL1 between the centers of the two first color sub-pixels 121 intersects with the second connection line CL2 between the center of the second color sub-pixel 122 and the center of the third color sub-pixel 123, and the length L1 of the orthographic projection of the third connection line CL3 between the center of any first color sub-pixel 121 and the center of the second color sub-pixel 122 on the second connection line CL2 is greater than the length L2 of the orthographic projection of the fourth connection line CL4 between the center of the first color sub-pixel 121 and the center of the third color sub-pixel 123 on the second connection line CL2. Therefore, when the array substrate is used to display the vertical lines extending along the extending direction of the first connection line CL1, and the first color sub-pixel 121 and the third color sub-pixel 123 both provide sensitive colors for human eyes, because the first color sub-pixel 121 is closer to the third color sub-pixel 123, the “sense of fluctuation” of the vertical lines seen by human eyes can be alleviated, so that the graininess of the display image can be alleviated or even eliminated, and the lines of the display image can be more continuous and natural.

As illustrated in FIG. 5, the shape of the first color sub-pixel 121 includes a rectangle. As illustrated in FIG. 5, the shape of the second color sub-pixel 122 includes a “T” shape, and the T shape includes a first rectangle portion 1221 extending in the first direction, a second rectangle portion 1222 extending in the second direction, and an arc portion 1223 at a connection position of the first rectangle portion 1221 and the second rectangle portion 1222. The shape of the third color sub-pixel 123 includes a rectangle. Thus, the shapes of the first color sub-pixel and the third color sub-pixel are simple and easy to manufacture, and the shape of the second color sub-pixel is beneficial to improve the space utilization of the array substrate, thereby optimizing the layout.

Similarly, as illustrated in FIG. 5, the shape of the first color sub-pixel 121 includes a pair of parallel edges 1214, the pair of parallel edges 1214 includes two parallel edges 1214A and 1214B, and the length of the parallel edge 1214A is equal to the length of the parallel edge 1214B. The shape of the second color sub-pixel 122 includes a pair of parallel edges 1224, the pair of parallel edges 1224 includes two parallel edges 1224A and 1224B, and the length of the parallel edge 1224A is greater than the length of the parallel edge 1224B. The shape of the third color sub-pixel 123 includes a pair of parallel edges 1234, and the pair of parallel edges 1234 includes two parallel edges 1234A and 1234B. Thus, when a fine metal mask (FMM) is used to fabricate the above-mentioned array substrate, the extending direction of the above-mentioned parallel edges can be the stretching direction of the fine metal mask (FMM), which is beneficial to the transmission of the fine metal mask (FMM) tension, thereby improving the product yield.

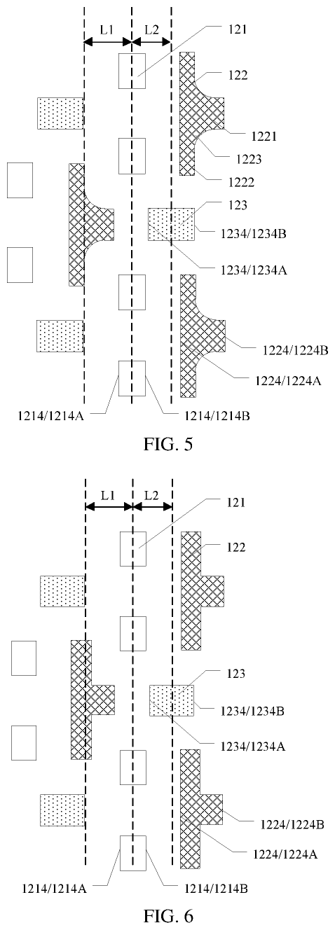

FIG. 6 is a schematic diagram of another array substrate provided by an embodiment of the present disclosure. As illustrated in FIG. 6, in each sub-pixel group 120, the first connection line CL1 between the centers of the two first color sub-pixels 121 intersects with the second connection line CL2 between the center of the second color sub-pixel 122 and the center of the third color sub-pixel 123, and the length L1 of the orthographic projection of the third connection line CL3 between the center of any first color sub-pixel 121 and the center of the second color sub-pixel 122 on the second connection line CL2 is greater than the length L2 of the orthographic projection of the fourth connection line CL4 between the center of the first color sub-pixel 121 and the center of the third color sub-pixel 123 on the second connection line CL2. Therefore, when the array substrate is used to display the vertical lines extending along the extending direction of the first connection line CL1, and the first color sub-pixel 121 and the third color sub-pixel 123 both provide sensitive colors for human eyes, because the first color sub-pixel 121 is closer to the third color sub-pixel 123, the “sense of fluctuation” of the vertical lines seen by human eyes can be alleviated, so that the graininess of the display image can be alleviated or even eliminated, and the lines of the display image can be more continuous and natural.

As illustrated in FIG. 6, the shape of the first color sub-pixel 121 includes a rectangle, the shape of the second color sub-pixel 122 includes a “T” shape, and the T shape includes a first rectangle portion 1221 extending in the first direction and a second rectangle portion 1222 extending in the second direction, and the shape of the third color sub-pixel 123 includes a rectangle. Thus, the shapes of the first color sub-pixel and the third color sub-pixel are simple and easy to manufacture, and the shape of the second color sub-pixel is beneficial to improve the space utilization of the array substrate, thereby optimizing the layout.

Similarly, as illustrated in FIG. 6, the shape of the first color sub-pixel 121 includes a pair of parallel edges 1214, and the pair of parallel edges 1214 includes two parallel edges 1214A and 1214B. The shape of the second color sub-pixel 122 includes a pair of parallel edges 1224, and the pair of parallel edges 1224 includes two parallel edges 1224A and 1224B. The shape of the third color sub-pixel 123 includes a pair of parallel edges 1234, and the pair of parallel edges 1234 includes two parallel edges 1234A and 1234B. Thus, when a fine metal mask (FMM) is used to fabricate the above-mentioned array substrate, the extending direction of the above-mentioned parallel edges can be the stretching direction of the fine metal mask (FMM), which is beneficial to the transmission of the fine metal mask (FMM) tension, thereby improving the product yield.

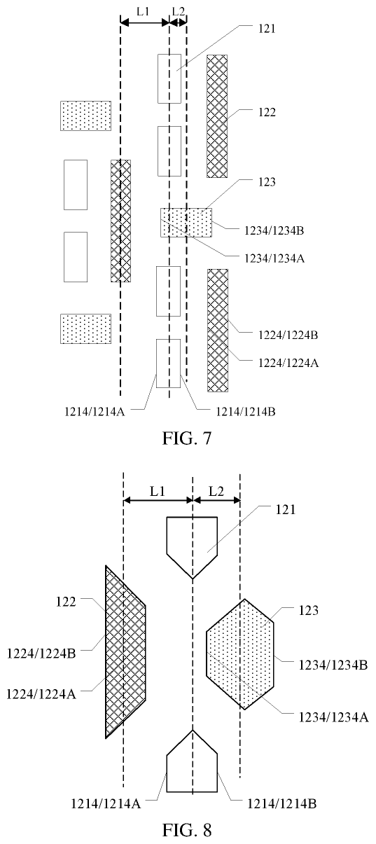

FIG. 7 is a schematic diagram of another array substrate provided by an embodiment of the present disclosure. As illustrated in FIG. 7, in each sub-pixel group 120, the first connection line CL1 between the centers of the two first color sub-pixels 121 intersects with the second connection line CL2 between the center of the second color sub-pixel 122 and the center of the third color sub-pixel 123, and the length L1 of the orthographic projection of the third connection line CL3 between the center of any first color sub-pixel 121 and the center of the second color sub-pixel 122 on the second connection line CL2 is greater than the length L2 of the orthographic projection of the fourth connection line CL4 between the center of the first color sub-pixel 121 and the center of the third color sub-pixel 123 on the second connection line CL2. Therefore, when the array substrate is used to display the vertical lines extending along the extending direction of the first connection line CL1, and the first color sub-pixel 121 and the third color sub-pixel 123 both provide sensitive colors for human eyes, because the first color sub-pixel 121 is closer to the third color sub-pixel 123, the “sense of fluctuation” of the vertical lines seen by human eyes can be alleviated, so that the graininess of the display image can be alleviated or even eliminated, and the lines of the display image can be more continuous and natural.

As illustrated in FIG. 7, the first color sub-pixel 121, the second color sub-pixel 122, and the third color sub-pixel 123 are all rectangular in shape. Therefore, the shapes of the first color sub-pixel, the second color sub-pixel, and the third color sub-pixel are simple and easy to manufacture, and the shape of the second color sub-pixel is beneficial to improve the space utilization of the array substrate, thereby optimizing the layout.

In some examples, as illustrated in FIG. 7, the third color sub-pixel 123 extends beyond the first connection line CL1 of the two first color sub-pixels 121, so that the first color sub-pixel 121 is closer to the second color sub-pixel 123 in the direction perpendicular to the first connection line CL1. Therefore, when the array substrate is used to display the vertical lines extending along the extending direction of the first connection line CL1, and the first color sub-pixel 121 and the third color sub-pixel 123 both provide sensitive colors for human eyes, because the first color sub-pixel 121 is closer to the third color sub-pixel 123, the “sense of fluctuation” of the vertical lines seen by human eyes can be alleviated, so that the graininess of the display image can be alleviated or even eliminated, and the lines of the display image can be more continuous and natural.

FIG. 8 is a schematic diagram of another array substrate provided by an embodiment of the present disclosure. As illustrated in FIG. 8, in each sub-pixel group 120, the first connection line CL1 between the centers of the two first color sub-pixels 121 intersects with the second connection line CL2 between the center of the second color sub-pixel 122 and the center of the third color sub-pixel 123, and the length L1 of the orthographic projection of the third connection line CL3 between the center of any first color sub-pixel 121 and the center of the second color sub-pixel 122 on the second connection line CL2 is greater than the length L2 of the orthographic projection of the fourth connection line CL4 between the center of the first color sub-pixel 121 and the center of the third color sub-pixel 123 on the second connection line CL2. Therefore, when the array substrate is used to display the vertical lines extending along the extending direction of the first connection line CL1, and the first color sub-pixel 121 and the third color sub-pixel 123 both provide sensitive colors for human eyes, because the first color sub-pixel 121 is closer to the third color sub-pixel 123, the “sense of fluctuation” of the vertical lines seen by human eyes can be alleviated, so that the graininess of the display image can be alleviated or even eliminated, and the lines of the display image can be more continuous and natural.

As illustrated in FIG. 8, the shape of the first color sub-pixel 121 is a right-angled base symmetrical pentagon, the shape of the second color sub-pixel 122 is a trapezoid, the trapezoid includes a pair of parallel edges 1224, and the pair of parallel edges 1224 includes two parallel edges 1224A and 1224B. The shape of the third color sub-pixel 123 is a hexagon, the hexagon includes a pair of parallel edges 1234, and the pair of parallel edges 1234 includes two parallel edges 1234A and 1234B. Thus, when a fine metal mask (FMM) is used to fabricate the above-mentioned array substrate, the extending direction of the above-mentioned parallel edges can be the stretching direction of the fine metal mask (FMM), which is beneficial to the transmission of the fine metal mask (FMM) tension, thereby improving the product yield.

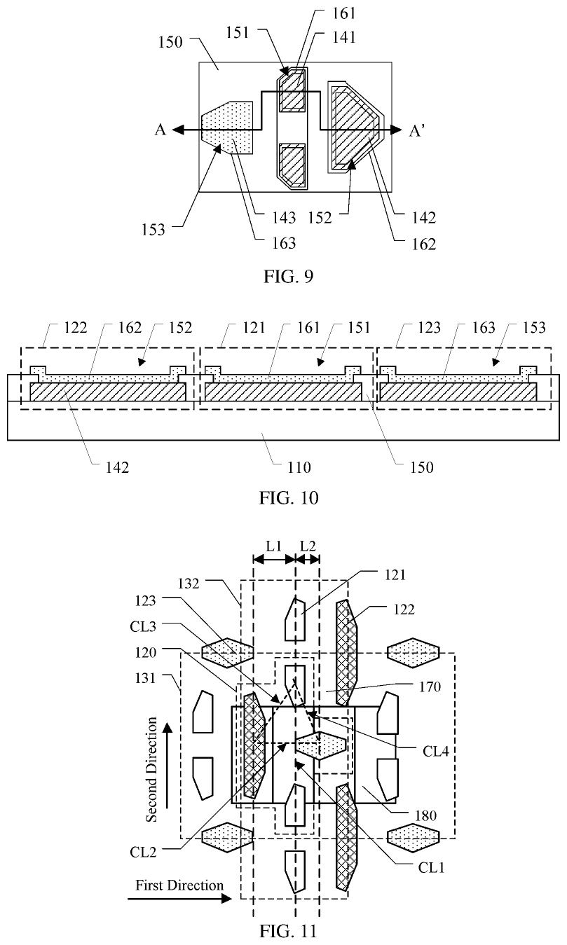

FIG. 9 is a schematic diagram of another array substrate provided by an embodiment of the present disclosure, and FIG. 10 is a schematic cross-sectional view of an array substrate along a direction AA′ in FIG. 9 provided by an embodiment of the present disclosure. As illustrated in FIG. 9 and FIG. 10, the array substrate 100 further includes a base substrate 110; a first color pixel electrode 141, a second color pixel electrode 142, and a third color pixel electrode 143, which are on the base substrate 110; a pixel defining layer 150 on a side of the first color pixel electrode 141, the second color pixel electrode 142, and the third color pixel electrode 143 away from the base substrate 110; and a first color light-emitting layer 161, a second color light-emitting layer 162, and a third color light-emitting layer 163 which are on a side of the pixel defining layer 150 away from the base substrate 110. The pixel defining layer 150 includes a first opening 151, a second opening 152, and a third opening 153, the first opening 151 exposes the first color pixel electrode 141, the second opening 152 exposes the second color pixel electrode 142, and the third opening 153 exposes the third color pixel electrode 143; the first color light-emitting layer 161 covers, through the first opening 151, a portion of the first color pixel electrode 141 exposed by the first opening 151; the second color light-emitting layer 162 covers, through the second opening 152, a portion of the second color pixel electrode 142 exposed by the second opening 152; and the third color light-emitting layer 163 covers, through the third opening 153, a portion of the third color pixel electrode 143 exposed by the third opening 153. In this case, a shape and a size of the first color sub-pixel 121 are defined by the first opening 151, a shape and a size of the second color sub-pixel 122 are defined by the second opening 152, and a shape and a size of the third color sub-pixel 123 are defined by the third opening 153. It should be noted that the above-mentioned light-emitting layer may not only include a light-emitting film layer, but may also include functional film layers such as an electron transport layer, an electron injection layer, a hole transport layer, a hole injection layer, etc.

In some examples, as illustrated in FIG. 9, two first color light-emitting layers 161 of two adjacent first color sub-pixels 121 may be integrated into one first color integrated light-emitting layer 161. That is, the two first color light-emitting layers 161 of the two first color sub-pixels 121 may be formed through the same opening of the same fine metal mask (FMM).

For example, as illustrated in FIG. 9, because the distance between the first color sub-pixel and the third color sub-pixel in the same sub-pixel group in the embodiments of the present disclosure is relatively short, first color light-emitting layers of the two first color sub-pixels in the same sub-pixel group may not be integrated together. On the contrary, in the sub-pixel column, two adjacent sub-pixel groups include a first sub-pixel group and a second sub-pixel group, and the first color sub-pixel in the first sub-pixel group close to the second sub-pixel group and the first color sub-pixel in the second sub-pixel group close to the first sub-pixel group may be integrated into one first color integrated light-emitting layer.

In some examples, as illustrated in FIG. 9, the orthographic projection of the first color integrated light-emitting layer 161 on the base substrate 110 simultaneously covers two first openings 151. In some examples, as illustrated in FIG. 9, the first color sub-pixel 121 may include the above-mentioned first color pixel electrode 141 and the first color light-emitting layer 161 disposed on the first color pixel electrode 141; the second color sub-pixel 122 includes the second color pixel electrode 142 and the second color light-emitting layer 162 disposed on the second color pixel electrode 142; and the third color sub-pixel 123 includes the third color pixel electrode 143 and the third color light-emitting layer 163 disposed on the third color pixel electrode 143.

For example, the first color pixel electrode 141 is configured to drive the first color light-emitting layer 161 to emit light of the first color, the second color pixel electrode 142 is configured to drive the second color light-emitting layer 162 to emit light of the second color, and the third color pixel electrode 143 is configured to drive the third color light-emitting layer 163 to emit light of the third color.

It should be noted that the shape and size of the above-mentioned first color sub-pixel may be the shape and size of the effective light-emitting region of the first color sub-pixel, which may be defined by the above-mentioned first via hole. Therefore, the shape of the first color pixel electrode may be different from the shape of the first color sub-pixel described above. Of course, the embodiments of the present disclosure include but are not limited thereto, and the shape of the first color pixel electrode may also be the same as the shape of the above-mentioned first color sub-pixel. Similarly, the shape and size of the above-mentioned second color sub-pixel may be the shape and size of the effective light-emitting region of the second color sub-pixel, which may be defined by the above-mentioned second via hole. Therefore, the shape of the second color pixel electrode may be the same as or different from the shape of the above-mentioned second color sub-pixel; and the shape and size of the above-mentioned third color sub-pixel may be the shape and size of the effective light-emitting region of the third color sub-pixel, which may be defined by the above-mentioned third via hole. Therefore, the shape of the third color pixel electrode may be the same as or different from the shape of the third color sub-pixel described above.

In another aspect, the specific shapes of the first color light-emitting layer, the second color light-emitting layer, and the third color light-emitting layer may be set according to the preparation process, which is not limited in the embodiments of the present disclosure. For example, the shape of the first color light-emitting layer may be determined by the shape of the opening of the mask in the manufacturing process.

In some examples, as illustrated in FIG. 9 and FIG. 10, the size of the first color pixel electrode 141 is larger than the size of the first opening 151, the size of the second color pixel electrode 142 is larger than the size of the second opening 152, and the size of the third color pixel electrode 143 is larger than the size of the third opening 153. Moreover, the distance of the first color pixel electrode 141 beyond the first opening 151, the distance of the second color pixel electrode 142 beyond the second opening 152, and the distance of the third color pixel electrode 143 beyond the third opening 153 are approximately equal. That is, the shortest distance between the edge of the first color pixel electrode 141 and the edge of the first opening 151, the shortest distance between the edge of the second color pixel electrode 142 and the edge of the second opening 152, and the shortest distance between the edge of the third color pixel electrode 143 and the edge of the third opening 153 are approximately equal.

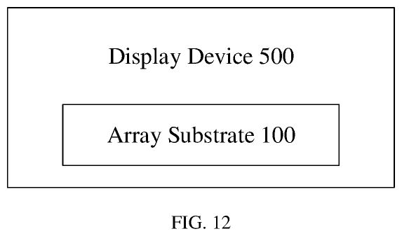

FIG. 11 is a schematic diagram of another array substrate provided by an embodiment of the present disclosure. As illustrated in FIG. 11, in each sub-pixel group 120, the first connection line CL1 between the centers of the two first color sub-pixels 121 intersects with the second connection line CL2 between the center of the second color sub-pixel 122 and the center of the third color sub-pixel 123, and the length L1 of the orthographic projection of the third connection line CL3 between the center of one first color sub-pixel 121 and the center of the second color sub-pixel 122 on the second connection line CL2 is different from the length L2 of the orthographic projection of the fourth connection line CL4 between the center of the same one first color sub-pixel 121 and the center of the third color sub-pixel 123 on the second connection line CL2. Therefore, when the array substrate is used to display the vertical lines extending along the extending direction of the first connection line CL1, and the first color sub-pixel 121 and the third color sub-pixel 123 both provide sensitive colors for human eyes, because the first color sub-pixel 121 is closer to the third color sub-pixel 123, the “fluctuation” of the vertical lines seen by human eyes can be alleviated, so that the graininess of the display image can be alleviated or even eliminated, and the lines of the display image can be more continuous and natural.

In some examples, as illustrated in FIG. 11, the length of the orthographic projection of the third connection line CL3 between the center of one first color sub-pixel 121 and the center of the second color sub-pixel 122 on the second connection line CL2 is greater than the length of the orthographic projection of the fourth connection line CL4 between the center of the same one first color sub-pixel 121 and the center of the third color sub-pixel 123 on the second connection line CL2.

In some examples, as illustrated in FIG. 11, in each sub-pixel group 120, in the direction of the third connection line, no other sub-pixel is provided between the first color sub-pixel 121 and the second color sub-pixel 122; and in the direction of the fourth connection line, no other sub-pixel is provided between the first color sub-pixel 121 and the third color sub-pixel 123.

In some examples, as illustrated in FIG. 11, the array substrate 100 further includes a sub-pixel interval 170 disposed between two adjacent sub-pixels, the sub-pixel is any one of a group consisting of the first color sub-pixel 121, the second color sub-pixel 122, and the third color sub-pixel 123, and each sub-pixel group 120 includes four sub-pixels separated by the sub-pixel interval 170.

In some examples, as illustrated in FIG. 11, the plurality of sub-pixel groups 120 are arranged along the first direction to form a plurality of sub-pixel group rows 131, and are arranged along the second direction intersecting with the first direction to form a plurality of sub-pixel group columns 132, and two adjacent sub-pixel group columns 132 are in a staggered arrangement. In the sub-pixel column 132, two adjacent sub-pixel groups 120 include a first sub-pixel group 1201 and a second sub-pixel group 1202, and a ratio of a distance between the vertex of the first color sub-pixel 121 away from the second sub-pixel group 1202 in the first sub-pixel group 1201 and the vertex of the first color sub-pixel 121 away from the first sub-pixel group 1201 in the second sub-pixel group 1202, to a size of the second color sub-pixel 122 in an extending direction of the first connection line ranges from 0.8 to 1.2. That is, thus, a ratio of a maximum distance of vertices of two first color sub-pixels with a minimum spacing in the first sub-pixel group and the second sub-pixel group, to a size of the second color sub-pixel in an extending direction of the first connection line ranges from 0.8 to 1.2. So that the arrangement of the pixels on the array substrate can be more uniform.

In some examples, the distance between the vertex of the first color sub-pixel 121 away from the second sub-pixel group 1202 in the first sub-pixel group 1201 and the vertex of the first color sub-pixel 121 away from the first sub-pixel group 1201 in the second sub-pixel group 1202 is approximately equal to the size of the second color sub-pixel 122 in the extending direction of the first connection line. For example, the ratio of the distance between the vertex of the first color sub-pixel 121 away from the second sub-pixel group 1202 in the first sub-pixel group 1201 and the vertex of the first color sub-pixel 121 away from the first sub-pixel group 1201 in the second sub-pixel group 1202, to the size of the second color sub-pixel 122 in the extending direction of the first connection line ranges from 0.9 to 1.1, so that the arrangement of the pixels on the array substrate can be more uniform, and the third color sub-pixel can be formed into a regular hexagon.

In some examples, the ratio of the size of the shape of the first color sub-pixel 121 in the extending direction of the first connection line CL1 to the size of the shape of the first color sub-pixel 121 in the extending direction of the second connection line CL2 ranges from 1.6 to 2.8.

For example, the ratio of the size of the shape of the first color sub-pixel 121 in the extending direction of the first connection line CL1 to the size of the shape of the first color sub-pixel 121 in the extending direction of the second connection line CL2 ranges from 1.8 to 2.6, such as 2.2.

In some examples, the ratio of the size of the shape of the second color sub-pixel 122 in the extending direction of the first connection line CL1 to the size of the shape of the second color sub-pixel 122 in the extending direction of the second connection line CL2 ranges from 4.3 to 6.7.

For example, the ratio of the size of the shape of the second color sub-pixel 122 in the extending direction of the first connection line CL1 to the size of the shape of the second color sub-pixel 122 in the extending direction of the second connection line CL2 ranges from 4.5 to 6.5, such as 5.5.

In some examples, the ratio of the size of the shape of the third color sub-pixel 123 in the extending direction of the first connection line CL1 to the size of the shape of the third color sub-pixel 123 in the extending direction of the second connection line CL2 ranges from 0.4 to 0.76.

For example, the ratio of the size of the shape of the third color sub-pixel 123 in the extending direction of the first connection line CL1 to the size of the shape of the third color sub-pixel 123 in the extending direction of the second connection line CL2 ranges from 0.5 to 0.66, such as 0.58.

In some examples, in each sub-pixel group 120, the orthographic projection of the second color sub-pixel 122 on the first connection line CL1 overlaps with the orthographic projection of the first color sub-pixel 121 on the first connection line CL1, and the orthographic projection of the third color sub-pixel 123 on the first connection line CL1 is not overlapped with the orthographic projection of the first color sub-pixel 121 on the first connection line CL1.

In some examples, in each sub-pixel group 120, the orthographic projection of the first color sub-pixel 121 on the second connection line CL2 overlaps with the orthographic projection 123 of the third color sub-pixel on the second connection line CL2.

In some examples, as illustrated in FIG. 11, the array substrate 100 further includes a plurality of pixel driving circuits 180, and the plurality of pixel driving circuits 180 are provided in a one-to-one correspondence with the plurality of sub-pixels. As illustrated in FIG. 11, one second color sub-pixel 122, one first color sub-pixel 121, and one third color sub-pixel 123 in a sub-pixel group 120, and one first color sub-pixel 121 in an adjacent sub-pixel group 120 in the first direction may be arranged in a one-to-one correspondence with four pixel driving circuits 180 arranged in sequence in the first direction. For example, the pixel electrode in the sub-pixel may be electrically connected to the corresponding pixel driving circuit through a via hole, and the via holes corresponding to the above-mentioned four pixel driving circuits may be located approximately on the same straight line.

FIG. 12 is a schematic diagram of a display device provided by an embodiment of the present disclosure. As illustrated in FIG. 12, the display device 500 includes the above-mentioned array substrate 100. Because the array substrate can reduce or even eliminate the graininess of the display image and allow the lines of the display image to be more continuous and natural, the display device has higher display quality. Also, the display device can achieve a higher pixel resolution with a relatively small number of sub-pixels.

For example, in some examples, the display device may be any product or component with a display function, such as a smart phone, a tablet computer, a TV, a display, a notebook computer, a digital photo frame, a navigator, etc.

The following points required to be explained:

(1) The drawings of the embodiments of the present disclosure only relate to the structures related to the embodiments of the present disclosure, and other structures can refer to the general design.

(2) Without conflict, the embodiments of the present disclosure and the features in the embodiments may be combined with each other to obtain new embodiments.

The above are only the specific embodiments of this disclosure, but the scope of protection of this disclosure is not limited to this. Any person familiar with this technical field can easily think of changes or substitutions within the technical scope disclosed in this disclosure, which should be covered by the scope of protection of this disclosure. Therefore, the scope of protection of this disclosure should be based on the scope of protection of the claims.

1. An array substrate, comprising:
a plurality of sub-pixel groups, wherein each of the sub-pixel groups comprises two first color sub-pixels, one second color sub-pixel, and one third color sub-pixel,
wherein, in each of the sub-pixel groups, a first connection line between centers of the two first color sub-pixels intersects with a second connection line between a center of the second color sub-pixel and a center of the third color sub-pixel, and a length of an orthographic projection of a third connection line, between a center of one of the first color sub-pixels and the center of the second color sub-pixel, on the second connection line is different from a length of an orthographic projection of a fourth connection line, between the center of the one of the first color sub-pixels and the center of the third color sub-pixel, on the second connection line.

2. The array substrate according to claim 1, wherein the length of the orthographic projection of the third connection line, between the center of the one of the first color sub-pixels and the center of the second color sub-pixel, on the second connection line is greater than the length of the orthographic projection of the fourth connection line, between the center of the one of the first color sub-pixels and the center of the third color sub-pixel, on the second connection line,
wherein a light-emitting efficiency of the second color sub-pixel is lower than a light-emitting efficiency of the third color sub-pixel.

3. The array substrate according to claim 1, wherein, in each of the sub-pixel groups, in a direction of the third connection line, no other sub-pixel is provided between the first color sub-pixel and the second color sub-pixel; and
in a direction of the fourth connection line, no other sub-pixel is provided between the first color sub-pixel and the third color sub-pixel.

4. The array substrate according to claim 1, further comprising:
a sub-pixel interval, wherein the sub-pixel interval is provided between two adjacent sub-pixels, and the sub-pixel is any one selected from a group consisting of the first color sub-pixel, the second color sub-pixel, and the third color sub-pixel,
wherein each of the sub-pixel groups comprises four sub-pixels separated by the sub-pixel interval.

5. The array substrate according to claim 1, wherein the second connection line, the third connection line, and the fourth connection line form a non-equilateral triangle.

6. (canceled)

7. (canceled)

8. The array substrate according to claim 1, wherein the plurality of sub-pixel groups are arranged along a first direction to form a plurality of sub-pixel group rows, the plurality of sub-pixel groups are arranged along a second direction intersecting with the first direction to form a plurality of sub-pixel group columns, and two adjacent sub-pixel group columns are in a staggered arrangement; and
in the sub-pixel group column, two adjacent sub-pixel groups comprise a first sub-pixel group and a second sub-pixel group, and a minimum distance between a center of the first color sub-pixel in the first sub-pixel group and a center of the first color sub-pixel in the second sub-pixel group is smaller than a length of the first connection line.

9. The array substrate according to claim 8, wherein the length of the first connection line is less than 90 μm.

10. The array substrate according to claim 8, wherein two adjacent first color sub-pixels in a first direction overlap with a straight line extending in the first direction.

11. The array substrate according to claim 8, wherein centers of two first color sub-pixels in the first sub-pixel group and centers of two first color sub-pixels in the second sub-pixel group are on one straight line.

12. The array substrate according to claim 1, wherein the plurality of sub-pixel groups are arranged along a first direction to form a plurality of sub-pixel group rows, the plurality of sub-pixel groups are arranged along a second direction intersecting with the first direction to form a plurality of sub-pixel group columns, and two adjacent sub-pixel group columns are in a staggered arrangement; and
in the sub-pixel group column, two adjacent sub-pixel groups comprise a first sub-pixel group and a second sub-pixel group, and a ratio of a maximum distance of vertices of two first color sub-pixels with a minimum spacing in the first sub-pixel group and the second sub-pixel group, to a size of the second color sub-pixel in an extending direction of the first connection line ranges from 0.8 to 1.2.

13. The array substrate according to claim 1, wherein a shape of the first color sub-pixel is a non-centrally symmetric polygon, a shape of the second color sub-pixel is a non-centrally symmetric polygon, and a shape of the third color sub-pixel is a non-centrally symmetric polygon.

14. The array substrate according to claim 1, wherein a ratio of a size of a shape of the first color sub-pixel in an extending direction of the first connection line to a size of a shape of the first color sub-pixel in an extending direction of the second connection line ranges from 1.6 to 2.8; and/or
a ratio of a size of a shape of the second color sub-pixel in the extending direction of the first connection line to a size of a shape of the second color sub-pixel in the extending direction of the second connection line ranges from 4.3 to 6.7; and/or
a ratio of a size of a shape of the third color sub-pixel in the extending direction of the first connection line to a size of a shape of the third color sub-pixel in the extending direction of the second connection line ranges from 0.4 to 0.76.

15. The array substrate according to claim 1, wherein, in each of the sub-pixel groups, an orthographic projection of the second color sub-pixel on the first connection line overlaps with an orthographic projection of the first color sub-pixel on the first connection line, and an orthographic projection of the third color sub-pixel on the first connection line is not overlapped with the orthographic projection of the first color sub-pixel on the first connection line.

16. (canceled)

17. (canceled)

18. The array substrate according to claim 1, wherein at least one of a group consisting of a shape of the second color sub-pixel and a shape of the third color sub-pixel comprises a pair of parallel edges, the pair of parallel edges comprises a first parallel edge and a second parallel edge, and a length of the first parallel edge is greater than a length of the second parallel edge; and
a distance between the first parallel edge and the first connection line is greater than a distance between the second parallel edge and the first connection line.

19. (canceled)

20. The array substrate according to claim 1, wherein at least one of a group consisting of a shape of the second color sub-pixel and a shape of the third color sub-pixel comprises a polygon, the polygon comprises two vertices, and a distance between the two vertices is a maximum size of the polygon in a second direction; and
the polygon is divided, by a connection line between the two vertices, into a first portion and a second portion which are on both sides of the connection line, and an area of the first portion is not equal to an area of the second portion.

21. The array substrate according to claim 20, wherein the polygon comprises a first edge and a second edge, the first edge and the second edge are parallel to each other and parallel to the connection line between the two vertices, a length of the first edge is greater than a length of the second edge, the first portion is a portion where the first edge of the polygon is located, the second portion is a portion where the second edge of the polygon is located, and a size of the first portion in the first direction is smaller than a size of the second portion in the first direction.

22. (canceled)

23. The array substrate according to claim 1, wherein a shape of the first color sub-pixel comprises a pair of parallel edges, the pair of parallel edges comprises two parallel edges, and in one of the sub-pixel groups, a length of one of the two parallel edges close to the second color sub-pixel is smaller than a length of another of the two parallel edges close to the third color sub-pixel.

24. (canceled)

25. The array substrate according to claim 1, further comprising:
a base substrate;
a first color pixel electrode, a second color pixel electrode, and a third color pixel electrode, which are on the base substrate;
a pixel defining layer, wherein the pixel defining layer is on a side of the first color pixel electrode, the second color pixel electrode, and the third color pixel electrode away from the base substrate, the pixel defining layer comprises a first opening, a second opening, and a third opening, the first opening exposes the first color pixel electrode, the second opening exposes the second color pixel electrode, and the third opening exposes the third color pixel electrode;
a first color light-emitting layer, wherein the first color light-emitting layer is on a side of the pixel defining layer away from the first color pixel electrode, and the first color light-emitting layer covers, through the first opening, a portion of the first color pixel electrode exposed by the first opening;
a second color light-emitting layer, wherein the second color light-emitting layer is on a side of the pixel defining layer away from the second color pixel electrode, and the second color light-emitting layer covers, through the second opening, a portion of the second color pixel electrode exposed by the second opening; and
a third color light-emitting layer, wherein the third color light-emitting layer is on a side of the pixel defining layer away from the third color pixel electrode, and the third color light-emitting layer covers, through the third opening, a portion of the third color pixel electrode exposed by the third opening,
wherein a shape and a size of the first color sub-pixel are defined by the first opening, a shape and a size of the second color sub-pixel are defined by the second opening, and a shape and a size of the third color sub-pixel are defined by the third opening.

26. The array substrate according to claim 25, wherein two first color light-emitting layers of two adjacent first color sub-pixels in an extending direction of the first connection line are integrated into one first color integrated light-emitting layer, and an orthographic projection of the first color integrated light-emitting layer on the base substrate covers two first openings.

27. A display device, comprising the array substrate according to claim 1.
